(19) United States
(12) Patent Application Publication
(10) Pub. No.: US 2012/0193804 A1
(43) Pub. Date: Aug. 2, 2012

(54) OHMIC CONNECTION USING WIDENED CONNECTION ZONES IN A PORTABLE ELECTRONIC OBJECT

(75) Inventor: Yannick Grasset, Vallauris (FR)

(73) Assignee: RFIDEAL, Vallauris (FR)

(21) Appl. No.: 13/389,224

(22) PCT Filed: Aug. 5, 2010
(86) PCT No.: PCT/FR2010/000565

§ 371 Date: Apr. 16, 2012

(30) Foreign Application Priority Data
Aug. 6, 2009 (FR) 09/03880

(51) Int. Cl. H01L 23/488; H01L 21/50

(52) U.S. Cl. 257/773; 438/106; 257/E23.023; 257/E21.499

(57) ABSTRACT

The invention relates to portable electronic objects comprising an integrated circuit chip, and a mounting having two connection terminals for a circuit, as well as to a method for manufacturing such objects. The invention is characterized in that the chip is provided, on the active surface thereof, with two widened connection zones, in particular connection plates, said connection plates being positioned opposite said terminals and electrically connected, by ohmic contact, to the latter, and in that the surface defined by the connection plates, at the surface of the active integrated circuit having said plates, is greater than ½ of the surface of said surface. The invention can be used, in particular, for RFID objects.

The present invention relates to portable electronic objects, in particular of the contactless type, comprising, on the one hand, an integrated circuit chip and, on the other hand, a substrate having two connection terminals, for example terminals of an antenna circuit. The present invention further relates to a method for manufacturing such objects.

The electronic portable objects according to the invention are objects having the format of a card, or a so-called smart card, having a contact-based mode of operation and/or a contactless mode of operation, or objects with various formats, which may for example be intended for radio frequency identification. The latter objects of diverse formats are commonly referred to as electronic tags or object inlays.

In prior art portable electronic objects the integrated circuit chip is generally in the form of a parallelepiped, one side of which, referred to as the active side, is provided with contact pads. These contact pads are very small with respect to the surface area of the active side. In one example, the active side of the chip is substantially square-shaped, with sides 600 μm in length, and the contact pads, two in number, are also generally square-shaped, with sides 80 μm in length. Therefore, it is possible to consider the contact pads as nearly point-sized connection areas on the active side of the chip.

When the object is a contactless portable object, connecting a prior art integrated circuit chip to the antenna circuit may be achieved by capacitive coupling, or by ohmic contact.

Connecting a chip to the antenna circuit through capacitive coupling is possible only for certain contactless portable objects that operate at relatively high frequencies, of at least a few hundred MHz. Capacitive coupling cannot be implemented in DC-operated objects. Moreover, in the case of capacitive coupling, the antenna is specific because of the change in impedance introduced by the capacitance of the connection.

When the connection is made by ohmic contact, either the connection is achieved by means of connection wires that are connected, on the one hand, to the contact pads, and on the other hand, to the antenna terminals, or the connection is achieved by means of bumps.

The technology for manufacturing portable contactless objects, in which the chip is electrically connected to the antenna circuit by ohmic contact through the use of connection wires, is well mastered, but has some drawbacks. For each connection wire, two welds are required, a first one at the connection pad and a second one at an antenna terminal. As a result, the manufacturing throughput of the objects is relatively low. In addition, the chip thus connected by means of the connection wires must be encapsulated within a protective resin, which increases the thickness of the object at the location of the chip.

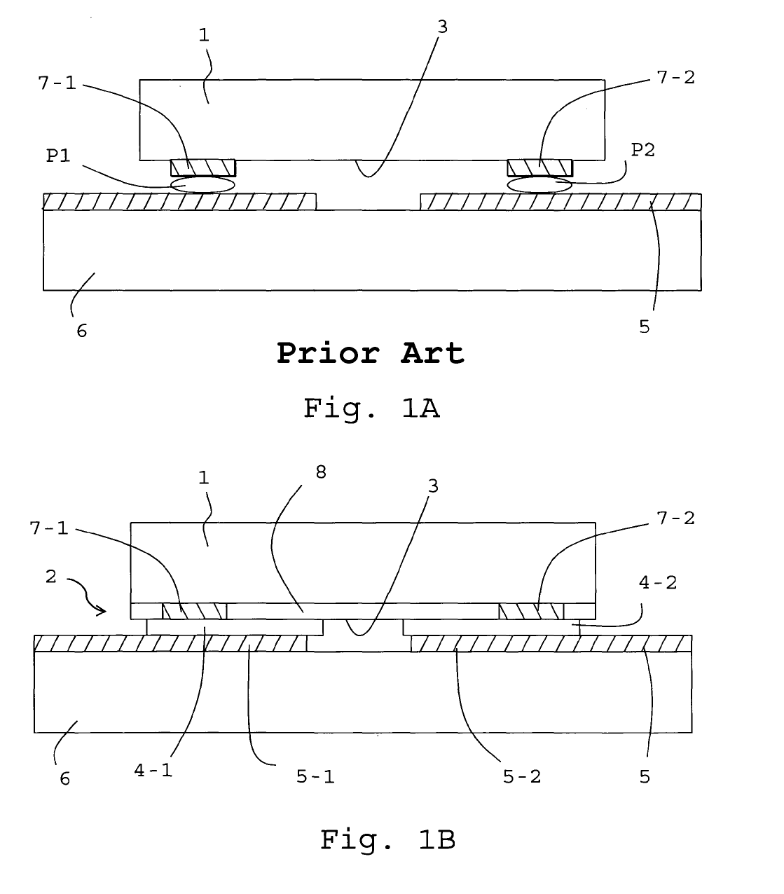

The technology for manufacturing contactless portable objects, in which the chip is electrically connected to the antenna circuit by ohmic contact through the use of bumps, is also well mastered, but difficult to implement and has some drawbacks. As shown in FIG. 1A, the bumps P1 and P2 are small gold beads or pyramids 20 to 50 μm in diameter (beads), or on edge (pyramids), deposited on the contact pads 7-1, 7-2, to allow for connection by ohmic contact to the antenna circuit 5, either by direct contact between the bump and the antenna, or by means of a conductive adhesive. The chip 1 is thus flipped over (“flip-chip”) onto the substrate 6. It therefore appears that the positioning tolerance of chip 1 on its substrate 6, which is provided with the antenna circuit 5, is small, thus slowing object production throughputs. According to the state of the art, the positioning accuracy required for the connection of an integrated circuit, which is flip-chip assembled onto a substrate provided with an antenna, is of the order of 15 to 20 micrometers.

In view of the above, a problem to be solved by the invention is to provide portable electronic objects, in particular of the contactless type, in which the chip is connected to the connection terminals of a circuit, in particular of an antenna circuit, as a flip-chip assembly, by ohmic contact, without requiring a connection by means of small bumps.

To solve this problem, a first object of the present invention is to provide a contactless portable object comprising, on the one hand an integrated circuit chip and, on the other hand, a substrate having two connection terminals of a circuit, characterized in that the chip is provided, on its active side, with two widened connection areas, said connection areas being positioned opposite said terminals and being electrically connected, by ohmic contact, to the latter, and in that the surface area defined by the connection areas on the active side of the integrated circuit having said connection areas is greater than ½ of the surface area of said side.

A second object of the present invention is to provide a method for manufacturing a portable electronic object comprising the steps of:

providing an integrated circuit chip having an active side, and a substrate having two connection terminals of a circuit;

providing two widened connection areas on the active side of the chip, the surface area defined by said connection areas on the active side of the integrated circuit carrying said connection areas being greater than ½ of the surface area of said side; and

flipping the chip over while electrically connecting the connection areas, by ohmic contact, to the circuit terminals.

Thus, the chip, which is flip-chip mounted onto the substrate, is not provided with bumps but with widened connection areas. Given the dimensions defined by said widened connection areas, the positioning constraints of the chip on the substrate for the connection are significantly reduced with respect to the constraints prevailing in the case where the chip is mounted by means of bumps.

The invention will be better understood from the following non-limiting description, with reference to the appended drawings, in which:

FIG. 1A schematically shows a cross-section of a prior art portable object, in which a chip provided with bumps is flip-chip mounted on a substrate with an antenna circuit;

FIG. 1B schematically shows a cross-section of a portable object according to the present invention, in which the chip is provided with large connection plates forming widened connection areas;

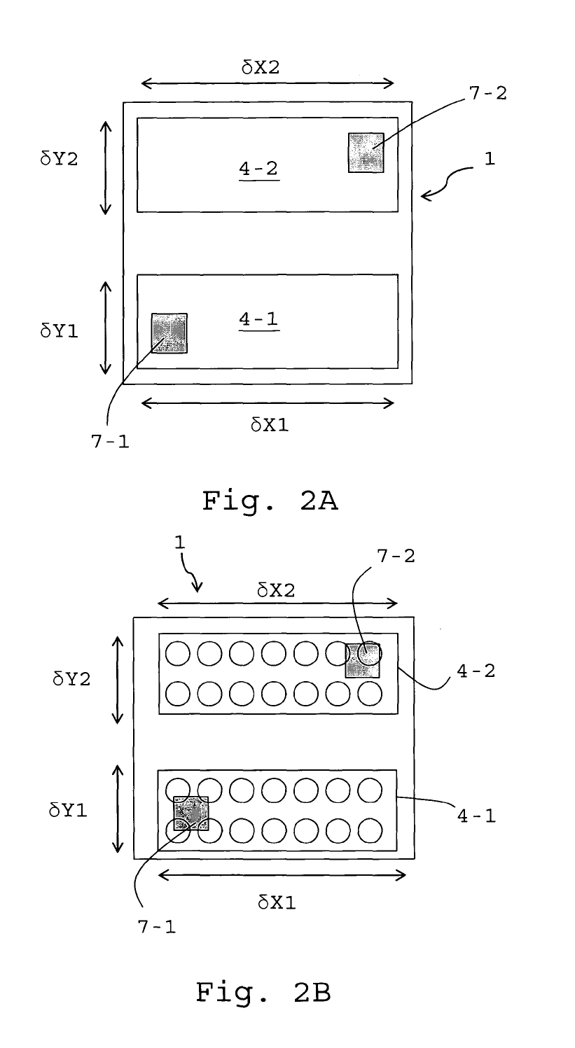

FIGS. 2A and 2B illustrate two embodiments of the present invention comprising widened connection areas according to the invention;

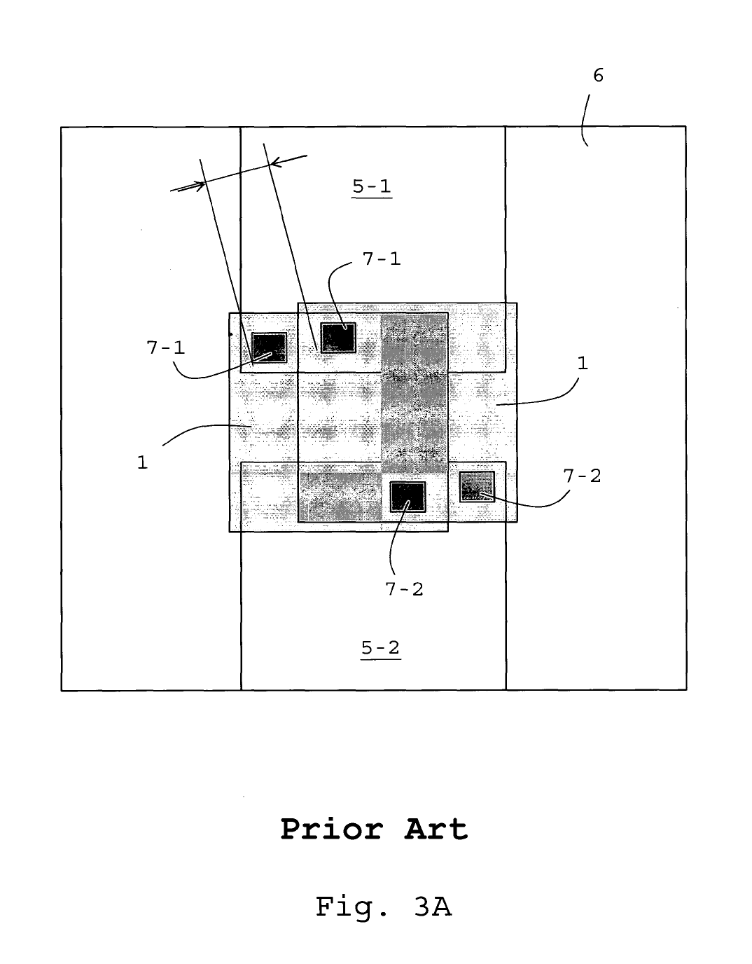

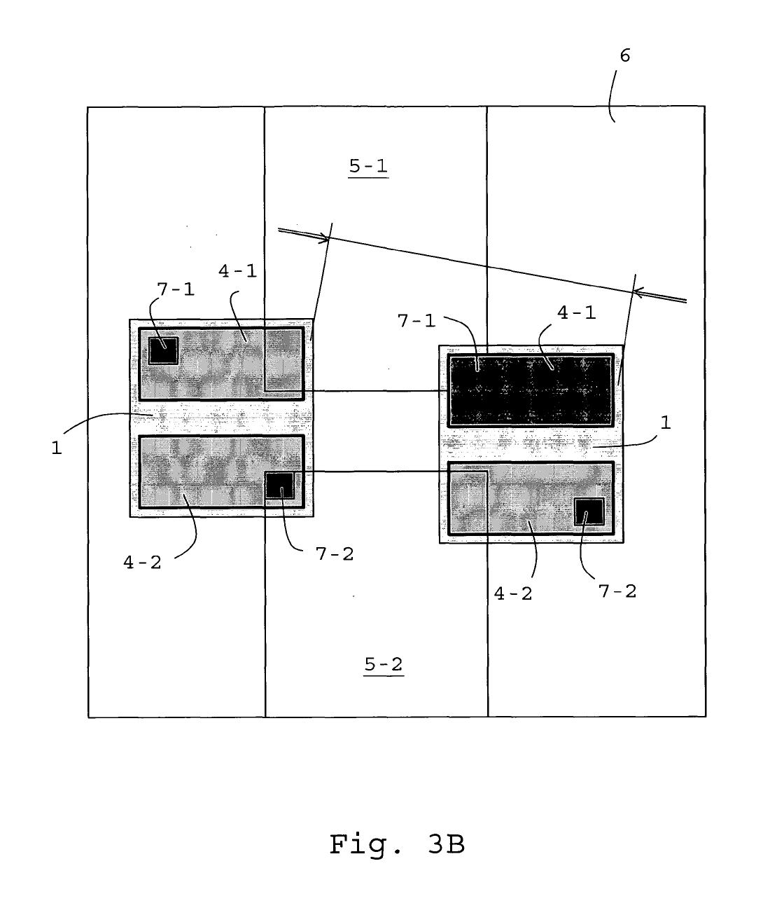

FIG. 3A illustrates a top view of the positioning constraints of a chip provided with bumps, which is flip-chip mounted on an antenna substrate for manufacturing a portable object according to the present invention; and

FIG. 3B illustrates a top view of the small positioning constraints which prevail when manufacturing a portable object according to the invention, the chip being provided with large plates forming widened connection areas.

The invention relates to portable electronic objects. Such portable electronic objects are, for example, smart cards having a standardized format, including subscriber identification modules (SIM) as well as objects of various sizes such as electronic labels or object inlays. The portable electronic objects according to the invention may have a contact-based and/or contactless mode of operation. In the event that such objects have both a contact-based mode of operation and a contactless mode of operation, these objects are said to be of the mixed, hybrid or dual-mode type. In a particular embodiment according to the invention, the portable objects are objects having a contactless mode of operation, which operate at an upper frequency of 13.56 MHz or at ultrahigh frequencies in the range between 860 and 960 MHz. However, these objects may operate at any frequency. They may even be DC-powered objects.

The portable objects according to the invention comprise a chip. This chip is a small-size, substantially parallelepiped-shaped integrated circuit chip.

The portable objects according to the invention further comprise a substrate which carries a circuit, such as an antenna circuit with two connection terminals. In some embodiments, the substrate is a dielectric substrate, for example made of paper, cardboard, PET, PVC or polyimide. In other embodiments, the substrate is an epoxy-type substrate provided with metal platings. In these other embodiments, wells are formed within the epoxy-type substrate for connection to the metal platings through their rear surface.

When the connection circuit is an antenna circuit, it defines a trace on the object substrate, whose tips form the connection terminals. The antenna circuit aimed at by the invention must therefore be considered in its broad sense as including conventional antenna circuits, as well as antenna stubs and conducting straps. In the latter case, the JEDEC MO283 standard defines a strap example that can be used to form an antenna circuit according to the invention.

The antenna circuit according to the invention is printed on the substrate's surface, for example, in particular by screen-printing, flexography or gravure printing, offset printing or ink-jet printing. The conducting ink used is preferably a polymer ink loaded with conducting elements such as silver, copper or carbon. In another example, the antenna circuit is made of a metal strip stamped and laminated onto the surface of the substrate, or even of a wound wire.

As is schematically shown in FIG. 1B, the chip 1 of the portable object 2 according to the invention is provided, on its active side 3, with two widened connection areas, for example continuous connection plates 4-1, 4-2, which are conductive across their entire surface. These plates 4-1, 4-2 are positioned opposite the terminals 5-1, 5-2 of the antenna circuit on the substrate 6. As a result, the chip 1 is placed in a flipped state for its positioning onto the substrate 6. The plates 4-1, 4-2 are formed of a conductive material. The latter may for example be a deposited metal or alloy of the aluminum, copper, gold, or AlSi type, or the like.

Furthermore, the surface of the active side 3 of the chip may, if required, carry contact pads 7-1, 7-2, which reach the surface through a passivation layer of said chip 1, and said active side is further provided with an insulating layer 8 having the connection plates 4-1, 4-2 connected to the contact pads 7-1, 7-2. Also, advantageously, the chips 1 used according to the invention are conventional chips produced by chip manufacturers, and could just as well be used for the manufacturing of prior art portable objects, which would however be subjected to post-processing according to the present invention, by depositing an insulating layer and the connection plates.

As can be seen in FIGS. 2A and 2B, the surface defined by the widened connection areas 4-1, 4-2, on the active side 3 of the integrated circuit chip 1 provided with said connection areas, is greater than ½ of the surface area of said side 3. In other words, the sum Σ of the surface area δX1×δY1 defined by area 4-1, added to the surface area δX2×δY2 defined by area 4-2, is greater than ½ of the surface area of the active side of the chip. When the connection areas are continuous plates, as is the case in FIG. 2A, the surface defined by one area is therefore coincident with the surface of the plate. In the embodiment of FIG. 2B, the connection areas are continuous plates on which a plurality of bumps have been placed. It can be noted that the bumps may, according to the present invention, have a non-commonly used shape such as rectangular, L-shaped, coil-shaped, spiral-shaped, with a footprint on the chip which would amount to a surface close to the size of the plates. It may also be noted that, according to alternative embodiments of the invention, the widened connection areas may be non-continuous. For example, they may comprise a set of conducting lines defining widened connection areas. In still further alternatives, the widened connection areas are plates, on the surface of which are formed a plurality of bumps scattered across the plates, in order to provide connection at multiple points.

The widened connection areas have a thickness in the range between 5 and 25 μm. For example, the thickness of the connection plate is of the order of 12 μm.

Advantageously, the surface area defined by the widened connection areas on the active side of the integrated circuit provided with said areas is greater than or equal to ⅔ of the surface area of said side.

In an example, the active side of the chip is a square with sides 300 to 800 μm in length. As a result, the surface area of the active side is in the range between 0.09 mm² and 0.64 mm². In this case, the surface defined by the connection areas will for example be substantially rectangular. It will cover ⅔ or more of the surface area of the active side.

It can be noted that the chip 1 is advantageously bonded to the substrate 5 by means of an either insulating or anisotropic Z-axis conductive adhesive providing the electric connection between the connection areas 4-1, 4-2 and the antenna terminals 5-1, 5-2. In other embodiments, the chip is bonded to the substrate by means of an insulating adhesive. In the latter embodiments, the electrical connection between the widened connection areas and the antenna terminals is provided by direct contact between the widened connection areas and the antenna terminals.

For the manufacture of portable objects according to the invention, in an example, an integrated circuit chip having an active side with two contact pads is provided. An insulator is deposited on said active side so that the contact areas are not covered by said insulator. Thereafter, the widened connection areas according to the invention are positioned so that they cover one half or two thirds of the surface area of said active side. The widened connection areas are electrically connected to the contact pads.

A substrate is then provided, which carries an antenna circuit with two terminals located close to one another, and an insulating adhesive or an anisotropic, Z-axis conductive adhesive is deposited onto the substrate, at the terminals.

The chip, which is provided with the widened connection areas, is then flipped over and positioned on the substrate so that the connection areas are positioned opposite the antenna terminals. The chip is in the same state as if it were bonded to the substrate by means of an insulating or anisotropic adhesive. The connection between the chip and the antenna circuit is of the ohmic type.

Referring now to FIGS. 3A and 3B, it may be seen that the constraints for positioning a chip 1 on its substrate 5 are much smaller, according to the invention (FIG. 3A), than in the prior art (FIG. 3B).

Indeed, it may be seen in FIG. 3B, that even with a small portion of a connection area opposite the antenna, a contact is always ensured on both areas, thus ensuring connection to the antenna. Thus, according to the present invention, the positioning tolerance of the chip is very large. Now referring to FIG. 3A, this shows the limitation due to the nearly point size contacts on the integrated circuit side. The prior art positioning constraints are much more stringent than those of the present invention.

Thus, assuming that, in order to be able to manufacture the antenna, the distance between the two tips of the antenna that are brought opposite the circuit must be kept at approximately 200 μm, the distance between the widened connection areas, advantageously between the large-size plates on the integrated circuit, can, for example, be as small as 100 μm. A positioning dispersion of plus or minus 50 μm with respect to the nominal position will have no effect on the contact along this axis. Similarly, the use of an antenna connector, which is wider by approximately 100 μm than the integrated circuit, will thus be such that a dispersion of plus or minus 50 μm with respect to the nominal position has no effect on the contact along this second axis.

In fact, the commonly used bump-based techniques require that the positioning be controlled within plus or minus 20 μm and have an impact on the electrical performance in the form of considerable dispersions. Thanks to the present invention the positioning tolerance can be significantly relaxed. For a dispersion of plus or minus 35 to 60 μm with respect to the nominal position, the assembly of the integrated circuit by means of widened contacts will not be subjected to any dispersion of its performance. In addition, extending the positioning tolerance beyond 35 to 60 μm can be envisaged.

Moreover, the use of connection plates according to the invention leads to a significantly superior ohmic connection on a surface with respect to the prior art. As a result, since the connection is made on a large surface, it will statistically not only be of a considerably improved quality, but will also guarantee a considerably better quality of connection.

Also, the functional throughput of assemblies according to the invention, for the manufacture of contactless portable objects, is greatly improved.

The usual dispersion of circuit assemblies for RFID applications leads to a variation in the coupling disturbances because of the presence of the antenna and/or the presence of a conducting adhesive. Once these large-size plates have been formed and once they have been positioned accurately on the integrated circuit, they contribute to form a shield. As a result, whatever the assembly dispersion may be, this shield masks its effects and ensures greater homogeneity of the electrical performance of the tag or inlay.

Furthermore, disturbance-induced dispersions are minimized, in particular in the case of UHF frequencies or higher. This results in larger degrees of freedom in antenna design and optimization, thus allowing for better energy reception and therefore, better operation in case of a weak field.

The use of large-size plates employed for a direct electrical contact also permits adaptation to low frequencies, for instance 13.56 MHz. Indeed, in most cases, the integrated circuit has an internal capacitance. To reduce the dispersion, a larger coupling capacitance must then be achieved. However, the internal capacitance is already of the order of 100 pF, which makes capacitive coupling difficult, if not impossible.

Of course, the invention is not restricted to the above described embodiments, and encompasses other embodiments, which, in particular, relate to portable objects that have both contact-based and contactless modes of operation, or even portable objects which only have contact-based modes of operation. In the latter case, the circuit's connection terminals are formed, for example, by the back contact terminals of the metal platings of a micromodule to be incorporated within a board body with a conventional smart card format or a SIM format. The micromodule will thus be extremely thin.

1. A portable electronic object comprising, on the one hand, an integrated circuit chip and, on the other hand, a substrate having an antenna circuit having two connection terminals, said chip being mounted in a flipped-over state on said substrate, and being provided, on its active side, with two widened connection areas, said connection areas being positioned opposite said terminals and being electrically connected, by ohmic contact, to the latter, and wherein the surface area defined by the connection areas on the active side of the integrated circuit having said connection areas is greater than ½ of the surface area of said side.

2. The portable object according to claim 1, having a contactless mode of operation.

3. The portable object according to claim 1, wherein the widened connection areas are connection plates.

4. The portable object according to claim 1, wherein the surface area defined by the widened connection areas on the active side of the integrated circuit chip provided with said areas is greater than or equal to ⅔ of the surface area of said side.

5. The portable object according to claim 1, wherein the active side of the chip has a surface area in the range between 0.09 mm² and 0.64 mm².

6. The portable object according to claim 1, wherein the surface of the active side of the chip carries contact pads, which reach the surface through a passivation layer of said chip, and wherein said active side is further provided with an insulating layer having the widened connection areas connected to the contact pads.

7. The object according to claim 1, wherein the chip is bonded to the substrate either by means of an anisotropic Z-axis conductive adhesive providing the electrical connection between the widened connection areas and the antenna terminals, or by means of an insulating adhesive.

8. The portable object according to claim 1, wherein said object is a RFID label operating at a high frequency of 13.56 MHz or at ultrahigh frequencies in the range between 860 and 960 MHz.

9. A method for manufacturing a portable electronic object, which comprises the steps of:
providing an integrated circuit chip having an active side, and a substrate having two connection terminals of an antenna circuit;
providing two widened connection areas on the active side of the chip, the surface area defined by said connection areas on the active side of the integrated circuit carrying said connection areas being greater than ½ of the surface area of said side; and
flipping the chip over and mounting the latter on its substrate to electrically connect the widened connection areas, by ohmic contact, to the circuit terminals.

10. The method according to claim 9, wherein the circuit is an antenna circuit and the portable electronic object is a contactless object.

11. The method according to claim 9, wherein the widened connection areas are connection plates.

12. The manufacturing method according to claim 9, wherein the surface of the active side of the chip carries contact pads, which reach its surface through a passivation layer of said chip and wherein said active side is further provided with an insulating layer having the widened connection areas connected to the contact pads.
